(19) United States
(12) Patent Application Publication
(10) Pub. No.: US 2024/0088032 A1
(43) Pub. Date: Mar. 14, 2024

(54) Structure and Method of Fabrication for High Performance Integrated Passive Device

(71) Applicant: Apple Inc., Cupertino, CA (US)

(72) Inventors: Vidhya Ramachandran, Cupertino, CA (US); Chi Nung Ni, Foster City, CA (US); Chueh-An Hsieh, Hsinchu County (TW); Rekha Govindaraj, San Jose, CA (US); Jun Zhai, Cupertino, CA (US); Long Huang, San Jose, CA (US); Rohan U. Mandrekar, Sunnyvale, CA (US); Saumya K. Gandhi, San Francisco, CA (US); Zhuo Yan, San Jose, CA (US); Yizhang Yang, Sunnyvale, CA (US); Saurabh P. Sinha, Austin, TX (US); Antonietta Oliva, Sausalito, CA (US)

(21) Appl. No.: 17/932,182

(22) Filed: Sep. 14, 2022

(51) Int. Cl. H01L 23/528; H01L 23/00; H01L 23/48; H01L 23/522; H01L 49/02

(52) U.S. Cl. CPC H01L 23/5283; H01L 23/481; H01L 23/5226; H01L 24/08; H01L 24/16; H01L 28/40; H01L 2224/08265; H01L 2224/16225

(57) ABSTRACT

Microelectronic modules are described. In an embodiment, a microelectronic module includes a module substrate, a chip mounted onto the module substrate, and a semiconductor-based integrated passive device between the chip and the module substrate. The semiconductor-based integrated passive device may include an upper RDL stack-up with thicker wiring layers than a lower BEOL stack-up. The semiconductor-based integrated passive device may be further solder bonded or hybrid bonded with the chip.

### BACKGROUND

### Field

Embodiments described herein relate to semiconductor packaging, and more specifically a module with an integrated passive device.

### Background Information

Microelectronic modules commonly include capacitors for a variety of reasons such as smoothing, filtering, bypassing, energy supply, etc. For example, a capacitor can be mounted onto a module substrate alongside another chip, such as a system-on-chip (SOC). Arranging these capacitors outside of the SOC can increase available area for the SOC since the capacitors are separate from the active SOC. This can lead to a lower power density (since larger capacitor can be realized), and increased efficiency. Additionally, since the capacitors are not required to be formed in the same substrate as the active SOC, processing sequences and substrate doping is not tied to SOC logic processing.

Multilayer ceramic capacitors (MLCCs) are the most commonly adopted technology for capacitor fabrication. MLCCs offer relatively high capacitance with low equivalent series inductance. More recently deep trench capacitors have been employed that utilize semiconductor fabrication processes. Such capacitors may have low profile and higher volume capacitance density than the MLCCs.

### SUMMARY

Microelectronic modules and methods of formation are described. In an embodiment, a microelectronic module includes a module substrate. a chip mounted onto the module substrate, and a semiconductor-based integrated passive device (IPD) between the chip and the module substrate. The semiconductor-based IPD may include a lower back-end-of-the-line (BEOL) stack-up, an upper redistribution layer (RDL) stack-up and a barrier layer therebetween, for example to provide protection against moisture ingress when the upper RDL stack-up includes organic interlayer dielectric (ILD) layers, which can also be implemented in order to create thicker metallization layers with higher metal density and provide lower effective series resistance (ESR) for the semiconductor-based IPD. A variety of additional variations are also described including structures in which the semiconductor-based IPD and chip are hybrid bonded, and in which the semiconductor-based IPD includes ILD layers formed of higher thermal conductivity materials. While several of these features are described and illustrated separately, it is to be appreciated that the various features may also be combined in some embodiments.

### BRIEF DESCRIPTION OF THE DRAWINGS

FIG. 1 is a cross-sectional side view illustration of microelectronic module including a semiconductor-based integrated passive device between a chip and a module substrate in accordance with an embodiment.

FIG. 2 is a close-up cross-sectional side view illustration of BEOL stack-ups for both a semiconductor-based integrated passive device bonded with a chip in accordance with an embodiment.

FIG. 3 is a cross-sectional side view illustration of microelectronic module including a semiconductor-based integrated passive device hybrid bonded with a chip in accordance with an embodiment

FIG. 4 is a close-up cross-sectional side view illustration of BEOL stack-ups for both a semiconductor-based integrated passive device hybrid bonded with a chip in accordance with an embodiment.

FIG. 5 is a process flow for a sequence of forming a microelectronic module including a semiconductor-based integrated passive device hybrid bonded with a chip including schematic top view and cross-sectional side view illustrations in accordance with an embodiment.

### DETAILED DESCRIPTION

Embodiments describe microelectronic modules including a chip and a semiconductor-based integrated passive device (IPD). In particular, the semiconductor-based IPD can be located between the chip and a module substrate rather than laterally adjacent to the chip on the module substrate.

In one aspect location of the semiconductor-based IPD directly underneath a chip can shorten circuit distance and reduce overall inductance. This may be useful for logic chips such as system-on-chip (SOC) including any of a central processing unit (CPU), graphics processing unit (GPU), compute Engine, etc. and combinations thereof that may operate at high power and high frequency. The semiconductor-based IPDs in accordance with embodiments can include capacitors, such as deep trench capacitors, that are fabricated using semiconductor processes and materials. This can allow for very fine features and thin films which can result in ultra-low inductance. It has been observed that such thin films and fine features can also result in higher equivalent series resistance (ESR). In accordance with embodiments, the semiconductor-based IPD can be fabricated using a lower back-end-of-the-line (BEOL) stack-up and an upper RDL stack-up that has thicker wiring layers and higher metal density than the lower BEOL stack-up to provide lower overall equivalent series inductance (ESL) and lower ESR. Notably, the lower BEOL stack-up can be fabricated in a silicon process line, with the upper RDL stack-up can be fabricated in a packaging process line where equipment is not limited to fine feature size and layer thickness. For example, dielectric layers in the lower BEOL stack-up may be deposited using vapor deposition technologies, which can be limited in thicknesses for time constraints. The dielectric layers in the upper RDL stack-up can be deposited using other suitable techniques, such as solution-based techniques that can achieve thicker layers, which leads to thicker metal layers for wiring.

The semiconductor-based IPDs in accordance with embodiments may additionally include through silicon vias (TSVs) to provide connection to the underlying module substrate. The TSVs may be further electrically connected to the upper RDL stack-up. In an exemplary semiconductor-based IPD capacitor structure, the capacitors can be banked (divided into an array of smaller capacitors), with the wiring layers in the upper RDL stack-up providing full power and ground planes. The TSVs can pass through the semiconductor-based IPD and connect the back side of the semiconductor-based IPD to the wiring layer(s) of the upper RDL stack-up which can be fabricated based on a package-like technology with ability to support thick metal and high metal density designs for minimizing resistance.

In accordance with embodiments the semiconductor-based IPDs include the additional upper RDL stack-up and TSVs to provide a component whose ESL and ESR are both low.

Additionally, the BEOL stack-ups allow the formation of a custom bump map, while allowing for a simple underlying IPD design. This can facilitate assembly of the IPD directly to a chip which may have a pre-defined and random bump map. In the case of reconfiguration of the chip bump map, the IPD can be updated by a simply design change in the upper RDL stack-up only, keeping the underlying IPD unchanged. Also, the same basic IPD can be reused multiple times in a design by dimply modifying the upper RDL stack-up. All of the features, make use and reuse of the IPD simple and relatively inexpensive compared to a full custom design that would be needed otherwise.

In another aspect, embodiments describe semiconductor-based IPDs in which hybrid bonding using wafer-on-wafer (WoW) or chip-on-wafer (CoW) techniques can be utilized to form lower impedance metal-mediated high density electrical connections with low profile standoff connectivity. Thermal degradation performance can additionally be improved by forming the upper RDL stack-up of the semiconductor-based IPD with a high thermal conductivity material (compared to silicon oxides and organics) such as silicon nitride (SiN), aluminum nitride (AlN), boron nitride (BN), alumina (Al₂O₃), and diamond. Such higher thermal conductivity materials may also have higher dielectric constants, which may be acceptable for an IPD where timing can be less important than for a higher performance chip.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “upper”, “lower”, “over”, “to”, “between”, and “on” as used herein may refer to a relative position of one layer with respect to other layers. One layer “over”, or “on” another layer or bonded “to” or in “contact” with another layer may be directly in contact with the other layer or may have one or more intervening layers. One layer “between” layers may be directly in contact with the layers or may have one or more intervening layers.

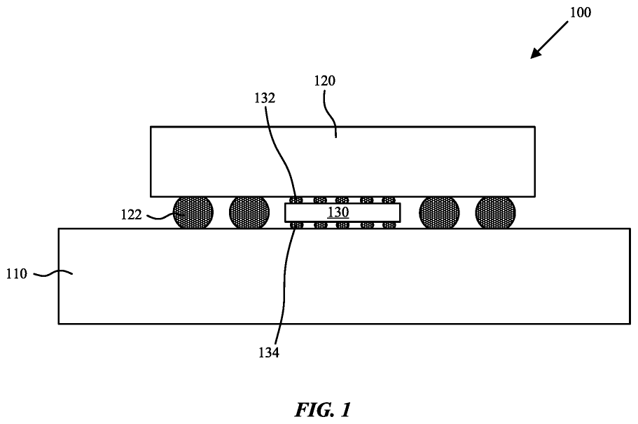

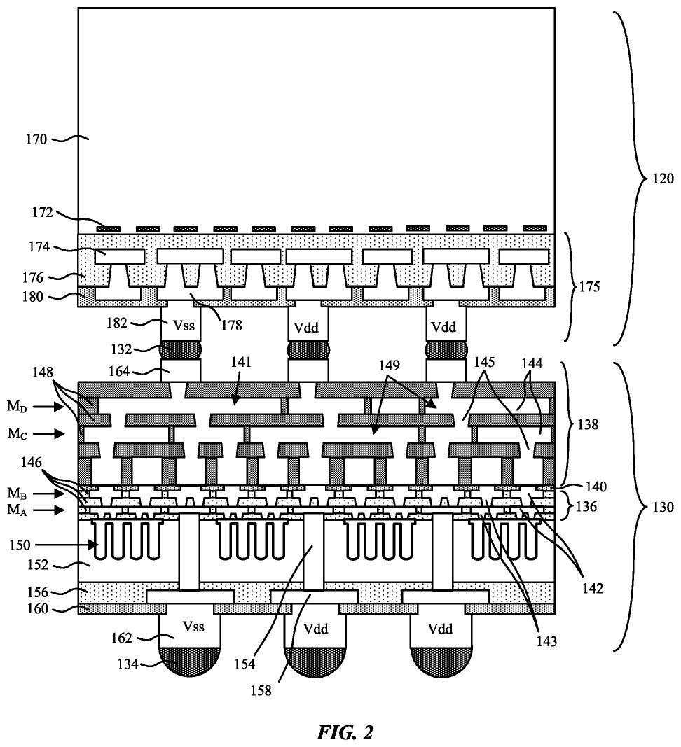

Referring now to FIGS. 1-2, FIG. 1 is a cross-sectional side view illustration of microelectronic module including a semiconductor-based integrated passive device between a chip and a module substrate in accordance with an embodiment, and FIG. 2 is a close-up cross-sectional side view illustration of BEOL stack-ups for both a semiconductor-based integrated passive device bonded with a chip in accordance with an embodiment. As shown, the microelectronic module 100 may include a module substrate 110, a chip 120 mounted onto the module substrate 110, and a semiconductor-based integrated passive device 130 between the chip and the module substrate. The module substrate 110 may be a printed circuit board (PCB) for example, including power supply lines and contacts, ground supply lines and contacts, etc. Various additional components can also be mounted onto the module substrate 110 including a power supply, and other peripheral components, packages, and systems.

The chip 120 may be mounted onto the module substrate 110 with ball grid array (BGA) solder bumps 122. The semiconductor-based integrated passive device 130 may be bonded to the chip 120 with a first set of (solder) microbumps 132, and bonded to the module substrate 110 with a second set of microbumps 134, both of which may be smaller than solder bumps 122, and my have a smaller pitch than solder bumps 122.

Referring now specifically to FIG. 2, in some embodiments the semiconductor-based integrated passive device includes a lower back-end-of-the-line (BEOL) stack-up 136, an upper RDL stack-up 138, and a barrier layer 140 between the upper RDL stack-up 138 and the lower BEOL stack-up 136. The barrier layer 140 may protect against the ingress of moisture for example into the lower BEOL stack-up 136. In an embodiment the barrier layer 140 includes a nitride material such as silicon nitride. The lower back-end-of-the-line (BEOL) stack-up 136 in accordance with embodiments may utilize a semiconductor fabrication plant processes and materials, which can allow for very fine features and thin films. These fine features can facilitate ultra-low inductance. It has been observed however that these thin films and fine features can cause high series resistance. While such series resistance could be overcome by wiring on the module substrate 110 if the semiconductor-based integrated passive device 130 is mounted laterally adjacent the chip 120, this becomes less feasible in a configuration such as FIG. 1 where the semiconductor-based integrated passive device 130 is mounted directly between the module chip 120 and module substrate 110. In accordance with embodiments, the upper RDL stack-up 138 is designed with larger features sizes and wiring layer widths and thicknesses. This may be accomplished by fabricating the upper RDL stack-up 138 with packaging fabrication plant processes, including deposition of organic interlayer dielectric (ILD) layers, which can be both thicker and more compliant than inorganic deposited ILD layers. The more compliant materials may thus facilitate higher wiring layer metal densities with lower susceptibility to strain induced failure.

In an embodiment, the lower BEOL stack-up includes one or more lower BEOL wiring layers 142, and the upper RDL stack-up includes one or more upper RDL wiring layers 144. The one or more lower BEOL wiring layers 142 may be formed within one or more lower metallization layers (M_{A}, M_{B}, etc.), and the one or more upper RDL wiring layers 144 may be formed within one or more upper metallization layer (M_{C}, M_{D}, etc.) that are thicker than the lower metallization layers. Thickness of the lower BEOL wiring layers 142 and upper RDL wiring layers 144 may be determined by thickness of the lower BEOL ILD layers 146 and upper RDL IDL layers 148. In an embodiment, the lower BEOL stack-up 136 includes lower oxide ILD layers 146, and the upper RDL stack-up 138 includes upper organic ILD layers 148. The lower ILD layers 146 may include nitrides, traditional oxides (e.g. silicon dioxide) as well as low dielectric constant (low-k) materials, many of which are also oxides. Exemplary low-k lower ILD layers 146 include carbon-doped oxides, fluorine-doped oxides, hydrogen-doped oxides, highly porous oxides such as aerogels and xerogels, and organics. The upper organic ILD layers 148, being formed of organic materials may be more compliant and facilitate metal densities of greater than 60% in the upper RDL wiring layers, or even higher metal densities such as 70% or even 90%. The upper metallization layers (M_{C}, M_{D}, etc.) may additionally include metal planes for power (Vdd) metal planes 149 and ground (Vss) metal planes 141.

By way example, the lower ILD layers 146 may be formed of nitride, oxide and low-k materials, and the lower metallization layers (M_{A}, M_{B}, etc.) may have thickness of less than 1 μm. Lower BEOL wiring layers 142 and vias 143 between lower metallization layers may have a width of less than 1 The upper ILD layers 148 may be formed of organic materials, and upper metallization layers (M_{C}, M_{D}, etc.) may have a thickness of 5 μm or more, such as 5-10 μm. Similarly, upper RDL wiring layers 144 and vias 145 between the upper metallization layers (M_{C}, M_{D}, etc.) may have widths of 5 μm or more, such as 5-10 μm, with Vdd metal planes and Vss metal planes being wider that the upper RDL wiring layers 144.

The semiconductor-based integrated passive device 130 in accordance with embodiments may include a plurality of trench capacitors 150. The trench capacitors 150 may be fabricated using a specific targeted process with optimized capacitors, or a DRAM fabrication process, for example. In an embodiment the semiconductor-based integrated passive device 130 includes a resistive substrate 152 (e.g. silicon substrate, or silicon-on-insulator (SOI) substrate) and the plurality of trench capacitors 150 may be formed within the resistive substrate 152, with the lower BEOL ILD layers 146 including dielectric and metallization layers for interconnection. The trench capacitors 150 in accordance with embodiments may include electrode layers formed of metal or other high conductivity materials. This lowers the equivalent self resistance. Furthermore, the upper RDL wiring layers 144 can interconnect the capacitor cells while keeping equivalent series resistance (ESR) low.

Still referring to FIG. 2, in accordance with embodiments through silicon vias (TSVs) 154 are provided through the resistive substrate 152 to provide power (Vdd) and ground (Vss) signals from the module substrate 110 to the trench capacitors 150 and to chip 120. It is to be appreciated that the designation of Vdd and Vss in FIG. 2 is exemplary, and for illustrational purposes. The back side of the semiconductor-based integrated passive device 130 may include an insulation layer 156 (e.g. oxide) formed on a back side of the substrate, contact pads 158, and passivation layer 160 (e.g. nitride, polyimide) formed on the contact pads 158. Metal bumps 162 may optionally extend from the contact pads 158 within openings in the passivation layer 160. Microbumps 134 (solder) may then be placed onto the optional metal bumps 162 or contact pads 158. For bonding with the module substrate. Metal bumps 164 (or alternatively contact pads) can also be included in the upper RDL stack-up 138 for connection with the chip 120. Chip 120 may be fabricated according to conventional semiconductor processing technologies including a semiconductor substrate 170, a plurality of active devices 172 (e.g. transistors, etc.) formed within the semiconductor substrate 170, and a chip-level BEOL stack-up 175. The chip-level BEOL stack-up 175 can include a plurality of metal wiring layers 174 and ILD layers 176 as common. While only a single metal wiring layer is illustrated, it is to be appreciated that the chip-level BEOL stack-up 175 may include any number of metal wiring layers and dielectric layers, such as 4, 8, 10, 12 etc. As shown, the chip-level BEOL stack-up 175 can additionally include a plurality of contact pads 178, passivation layer 180, and optional metal bumps 182 extending from the contact pads 178 and through openings in the passivation layer 180.

In the particular embodiments illustrated in FIGS. 1-2 the semiconductor-based integrated passive device 130 is solder bonded to the chip 120 and is solder bonded to the module substrate 110. For example, the semiconductor-based integrated passive device 130 can be laterally adjacent a plurality of chip solder bumps 122 connecting the chip 120 to the module substrate 110. Embodiments are not so limited. In some embodiments the semiconductor-based integrated passive device 130 can be hybrid bonded to the chip 120. For example, the chip-level BEOL stack-up 175 and the upper RDL stack-up 138 can be hybrid bonded together with an oxide-oxide dielectric surface and metal-metal contacts. In some embodiments the upper ILD layers 148 can be characterized by a higher thermal conductivity than the lower ILD layers 146 and/or ILD layers 176 of the chip-level BEOL stack-up 175.

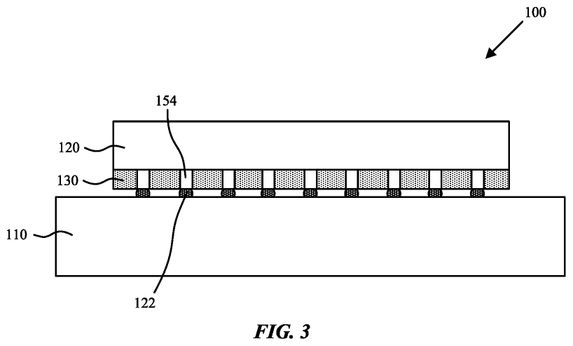

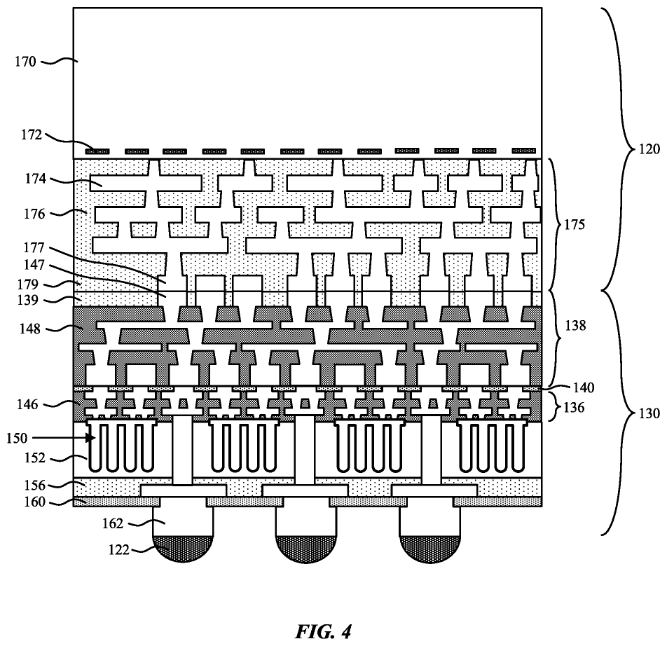

Referring now to FIGS. 3-4, FIG. 3 is a cross-sectional side view illustration of microelectronic module including a semiconductor-based integrated passive device hybrid bonded with a chip in accordance with an embodiment, and FIG. 4 is a close-up cross-sectional side view illustration of BEOL stack-ups for both a semiconductor-based integrated passive device hybrid bonded with a chip 120 in accordance with an embodiment. As shown, the semiconductor-based integrated passive device 130 includes an upper RDL stack-up 138, and the chip 120 includes a chip-level BEOL stack-up 175, and the upper RDL stack-up 138 is hybrid bonded to the chip-level BEOL stack-up 175 with an oxide-oxide dielectric interface and metal-metal contact interface. For example, the oxide-oxide dielectric interface may be between dielectric layers 139, 179 (e.g. silicon dioxide) and the metal-metal contact interface may be between contact pads 147, 177 (e.g. copper).

It is to be appreciated that the upper RDL stack-up 138 and lower BEOL stack-up 136 may be formed as previously described with regard to FIGS. 1-2. In some embodiments the upper RDL stack-up 138 and lower BEOL stack-up 136 can be similarly formed, for example, with similar processes and with similarly formed ILD layers, however this is not required. In an embodiment, at least the upper RDL stack-up 138 is formed of upper ILD layers 148 characterized by a higher thermal conductivity than the chip ILD layers 176. For example, the upper ILD layers 148 can be formed of materials such as silicon nitride (SiN), aluminum nitride (AlN), boron nitride (BN), alumina (Al₂O₃), and diamond. Such higher thermal conductivity materials may also have higher dielectric constants, which may be acceptable for an IPD since timing can be less important than for a higher performance chip. Such higher thermal conductivity materials can reduce system thermal resistance, and improve thermal degradation performance of the chip. In other embodiments, the upper ILD layers 148 can be formed of organic materials, for example formed using packaging assembly processes. Hybrid bonding still provides for low profile standoff with low impedance. Hybrid bonding in accordance with embodiments can be accomplished with both wafer-on-wafer (WoW) techniques and chip-on-wafer (CoW) techniques. For example, in a WoW technique chip singulation may result in a hybrid chip in which the semiconductor-based integrated passive device 130 that is as wide as the chip 120. In a CoW technique multiple semiconductor-based integrated passive devices 130 can be hybrid bonded to a wafer including an array of chips 120 prior to singulation, or vice versa. In this manner, the semiconductor-based integrated passive devices 130 can still be narrower than the chip 120 widths.

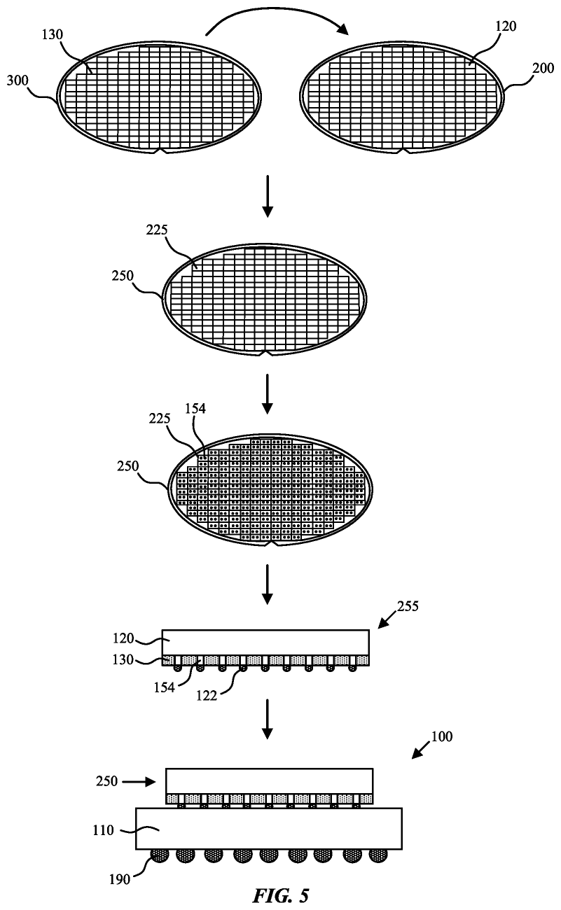

FIG. 5 is a process flow for a sequence of forming a microelectronic module including a semiconductor-based integrated passive device hybrid bonded with a chip including schematic top view and cross-sectional side view illustrations in accordance with an embodiment. As shown, the sequence may begin with aligning a wafer 300 including an array of semiconductor-based integrated passive device 130 areas and a wafer 200 including an array of chip 120 areas. The pair of wafers can then be hybrid bonded with heat and pressure to form a composite wafer 250 including hybrid bonded areas 225 of semiconductor-based integrated passive devices 130 and chips 120. The wafer 300 including the array of semiconductor-based integrated passive devices 130 can then be thinned, followed by formation of TSVs 154, solder bump 122 drop, and singulation (wafer saw) into a plurality of composite chips 255. The composite chips 255 can then be further packaged and mounted onto the module substrate 110. A plurality of module solder bumps 190 can optionally be placed on an opposite side of the module substrate 110 for further integration.

In utilizing the various aspects of the embodiments, it would become apparent to one skilled in the art that combinations or variations of the above embodiments are possible for forming an electronic module with a semiconductor-based integrated passive device. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. A microelectronic module comprising:
a module substrate;
a chip mounted onto the module substrate;
a semiconductor-based integrated passive device between the chip and the module substrate.

2. The microelectronic module of claim 1, wherein the semiconductor-based integrated passive device includes:
a lower back-end-of-the-line (BEOL) stack-up;
an upper redistribution layer (RDL) stack-up;
a barrier layer between the upper RDL stack-up and the lower BEOL stack-up.

3. The microelectronic module of claim 2, wherein the barrier layer comprises a nitride material.

4. The microelectronic module of claim 2, where the lower BEOL stack-up includes lower BEOL wiring layers, and the upper RDL stack-up includes upper RDL wiring layers, wherein the upper RDL wiring layers are thicker than the lower BEOL wiring layers.

5. The microelectronic module of claim 4, wherein the upper RDL wiring layers are characterized by a metal density of greater than 60%.

6. The microelectronic module of claim 4, wherein the lower BEOL stack-up includes lower interlayer dielectric (ILD) layers, and the upper RDL stack-up includes upper organic ILD layers.

7. The microelectronic module of claim 4, wherein the lower BEOL stack-up includes lower ILD layers, and the upper RDL stack-up includes upper ILD layers characterized by a higher thermal conductivity than the lower ILD layers.

8. The microelectronic module of claim 4, wherein the semiconductor-based integrated passive device includes an array of trench capacitors.

9. The microelectronic module of claim 4, wherein the semiconductor-based integrated passive device includes through silicon vias (TSVs).

10. The microelectronic module of claim 9, wherein the semiconductor-based integrated passive device is solder bonded to the chip and is solder bonded to the module substrate.

11. The microelectronic module of claim 10, wherein the semiconductor-based integrated passive device is laterally adjacent a plurality of chip solder bumps connecting the chip to the module substrate.

12. The microelectronic module of claim 1, wherein the semiconductor-based integrated passive device includes an upper RDL stack-up, and the chip includes a chip-level BEOL stack-up, and the upper RDL stack-up is hybrid bonded to the chip-level BEOL stack-up with an oxide-oxide dielectric interface and metal-metal contact interfaces.

13. The microelectronic module of claim 12, wherein the upper RDL stack-up includes upper ILD layers and the chip-level BEOL stack-up includes chip ILD layers, and the upper ILD layers are characterized by a higher thermal conductivity than the chip ILD layers.

14. The microelectronic module of claim 13, wherein the semiconductor-based integrated passive device is as wide as the chip.

15. The microelectronic module of claim 13, wherein the semiconductor-based integrated passive device includes:
a lower back-end-of-the-line (BEOL) stack-up; and
a barrier layer between the upper RDL stack-up and the lower BEOL stack-up.

16. The microelectronic module of claim 15, wherein the barrier layer comprises a nitride material.

17. The microelectronic module of claim 15, where the lower BEOL stack-up includes lower BEOL wiring layers, and the upper RDL stack-up includes upper RDL wiring layers, wherein the upper RDL wiring layers are thicker than the lower BEOL wiring layers.

18. The microelectronic module of claim 17, wherein the lower BEOL stack-up includes lower interlayer dielectric (ILD) layers, and the upper RDL stack-up includes upper organic ILD layers.

19. The microelectronic module of claim 15, wherein the semiconductor-based integrated passive device includes an array of trench capacitors.

20. The microelectronic module of claim 15, wherein the semiconductor-based integrated passive device includes through silicon vias (TSVs).
